(19) United States
(12) Patent Application Publication
(10) Pub. No.: US 2025/0112440 A1
(43) Pub. Date: Apr. 3, 2025

(54) PHOTOCONDUCTIVE SWITCH LASER DIODE DRIVER

(71) Applicants: Lawrence Livermore National Security, LLC, Livermore, CA (US); SoCal Simulations, LLC, Sacramento, CA (US)

(72) Inventors: Joseph Devin Schneider, Danville, CA (US); Sara Harrison, Livermore, CA (US); Alexander Peter Povilus, Livermore, CA (US); Caitlin Anne Chapin, Fremont, CA (US); Soroush Ghandiparsi, Pleasant Hill, CA (US); John Berns Lancaster, Livermore, CA (US); Lars F. Voss, Livermore, CA (US); Benjamin Fasenfest, Torrance, CA (US)

(21) Appl. No.: 18/476,681

(22) Filed: Sep. 28, 2023

(51) Int. Cl. H01S 5/06; H01S 5/32

(52) U.S. Cl. CPC H01S 5/0608; H01S 5/3226; H01S 5/3228

(57) ABSTRACT

Devices, methods and techniques related to the use of a photoconductive semiconductor switch (PCSS) to drive a high-power laser diode for a wide range of pulse widths are disclosed. In one example aspect, a circuit for driving one or more laser diodes includes an input port configured to be coupled to a voltage input, one or more inductors that are configured to be in series with the one or more laser diodes, a photoconductive switch coupled with the one or more inductors, and an output port configured to be coupled to the one or more laser diodes.

### STATEMENT REGARDING FEDERALLY SPONSORED RESEARCH OR DEVELOPMENT

This invention was made with Government support under Contract No. DE-AC52-07NA27344 awarded by the United States Department of Energy. The Government has certain rights in the invention.

### TECHNICAL FIELD

This document generally relates to electric circuitry, and more specifically, driver circuits for driving laser diodes.

### BACKGROUND

A laser diode is a semiconductor device similar to a light-emitting diode in which a diode pumped directly with electrical current can create lasing conditions at the diode's junction. Laser diodes have been heavily modified in recent years to accommodate modern technology, including but not limited to telecommunications, scanning and spectrometry, and medical uses.

### BRIEF DESCRIPTION OF THE DRAWINGS

FIG. 1 illustrates a schematic diagram of an example photoconductive semiconductor switch (PCSS) using a Silicon Carbide (SiC).

FIG. 2 illustrates an example experimental result of the PicoLAS driver module.

FIG. 3 illustrates an example driver model that simulates the behavior of the PicoLAS driver module.

FIG. 4 illustrates an example experimental result corresponding to the example circuit model of FIG. 3.

FIG. 5 illustrates example current plots with different inductance values in a driver model.

FIG. 6 illustrates an example current plot of the simple diode model.

FIG. 7 illustrates an example diode model considering the addition of a Zener diode.

FIG. 8 illustrates an example current plot corresponding to the example diode model in FIG. 7.

FIG. 9 illustrates an example parasitic diode model.

FIG. 10 illustrates an example current plot corresponding to example parasitic diode model in FIG. 9.

FIG. 11 illustrates an example circuit model in which a switch is in series with a diode in accordance with one or more embodiments of the present technology.

FIG. 12 illustrates an example plot of laser and voltage output corresponding to the example circuit model in FIG. 11.

FIG. 13 illustrates a ringing effect observed after connecting a simple diode model with inductive parasitic to a circuit model.

FIG. 14 illustrates an example current plot after introducing the matching resister in accordance with one or more embodiments of the present technology.

FIG. 15 illustrates example current plots of various on-resistance values in accordance with one or more embodiments of the present technology.

FIG. 16 illustrates an example current plot of five diodes connected in series in accordance with one or more embodiments of the present technology.

FIG. 17 illustrates an example configuration using an impedance transformer in accordance with one or more embodiments of the present technology.

FIG. 18 illustrates an example circuit model in which a switch is in parallel with a diode in accordance with one or more embodiments of the present technology.

FIG. 19 illustrates an example configuration in which the diode and resister are in parallel in accordance with one or more embodiments of the present technology.

FIG. 20 illustrates an example current plot showing late-time reflections.

FIG. 21A illustrates a top view of a first option using two circuit boards of difference sizes in accordance with one or more embodiments of the present technology.

FIG. 21B illustrates a bottom view of the first option in accordance with one or more embodiments of the present technology.

FIG. 22A illustrates a top view of a second option using a separate circuit board in accordance with one or more embodiments of the present technology.

FIG. 22B illustrates a bottom view of the second option using a separate circuit board in accordance with one or more embodiments of the present technology.

FIG. 23 illustrates an example configuration in accordance with one or more embodiments of the present technology.

FIG. 24 illustrates example current plots of an example implementation of option 1, an example implementation of option 2, and a simulated circuit model.

FIG. 25 illustrates example current plots of 2 kV and 120V in accordance with one or more embodiments of the present technology.

FIG. 26 illustrates a schematic diagram of a diamond switch.

FIG. 27 illustrates example current plots of an example 100 μm diamond layer, 500 μm diamond layer, and 1 mm SiC layer in accordance with one or more embodiments of the present technology.

FIG. 28 is a flowchart representation of a method for driving one or more laser diodes in accordance with one or more embodiments of the present technology.

### DETAILED DESCRIPTION

A laser diode is a semiconductor device in which a diode pumped directly with electrical current can create lasing conditions at the diode's junction. Currently, a common way to drive laser diodes is to use a charging capacitor with a fast-switching Metal-Oxide-Semiconductor Field-Effect Transistor (MOSFET). However, MOSFETs are ultimately limited in switching speed (e.g., about 1 ns) and the amount of current (e.g., about 30 A) they can supply.

This patent document, among other features, discloses techniques that can be implemented in various embodiments to use a photoconductive semiconductor switch (PCSS) to drive a high-power laser diode with a wide range of pulse widths, including ultra-short pulse widths that are shorter than 50 ps.

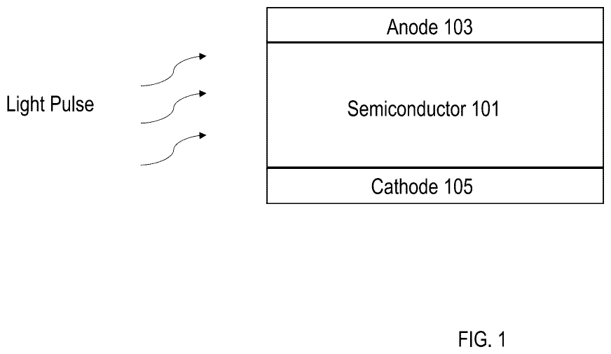

A PCSS is an electrical switch that uses the photoconductivity of a material to conduct electricity. FIG. 1 illustrates a schematic diagram of an example PCSS using a Silicon Carbide (SiC). The example PCSS includes a semiconductor material 101 that is coupled to an anode 103 and a cathode 105. A light pulse can be used to turn on/off the switch. These devices operate by suppling a high voltage (e.g., >10 kV) to one side of the switch. A short pulse of light illuminates the semiconductor instantly turning it from highly resistive (e.g., >100 GOhm) to sub 10 Ohm resistance. After the pulse ends, carriers quickly recombine, and the material returns to its highly resistive off state. PCSSs are commonly used to drive loads such as antennas. They can also be designed to drive loads such as laser diodes, thereby enabling ultrafast pulsing of off-the-shelf laser diodes. Using a PCSS to drive a laser diode increases the supply current by an order of magnitude and reduces the switching time to 10s of picoseconds. Furthermore, using the disclosed techniques, a single PCSS can be used to drive an arbitrary number of laser diodes.

In order to provide the desired PCSS drive for laser diodes, behaviors of existing laser drivers and laser diodes are studied and modeled to determine the changes needed in the circuit to achieve the ultra-short pulse widths. It is noted that a diode's capacitance is not constant—it varies with the voltage level in both reverse and forward-bias configurations. For a laser diode, there are additional time delays in turn on/off as the photons produce adequate gain in the laser cavity or decay from the cavity. Proper modeling can help determine whether the intrinsic properties of the laser diode impose a limitation on the speed more so than the electrical drive network.

Experiments described below were conducted using a PicoLAS LDP-AV D06-N10 pulse driver module that is capable of achieve 1 ns pulse duration and a rise time shorter than 900 ps, and Osram PLPT9 450LB_E laser diode package having a 5 W peak output power and 4 A current draw. The descriptions below serve as an example, and similar modeling techniques can be used to model the behavior of other types of pulse driver modules and diode packages.

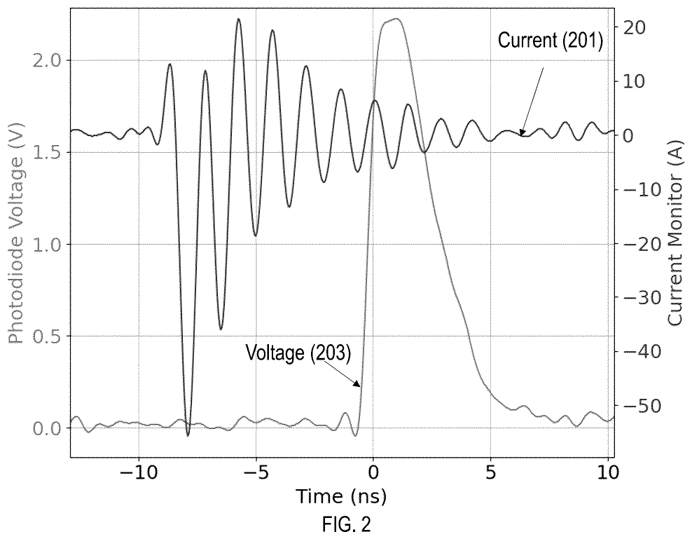

FIG. 2 illustrates an example experimental result of the PicoLAS driver module. As shown in FIG. 2, the current monitor observes ringing (oscillation of a signal) in the current (201) in response to the sudden change in input. The laser voltage output (203) does not track every ripple of the current ringing. While the laser output has a Full Width at Half-Maximum (FWHM) of ˜2.5 ns or so, the current oscillations have a full period of around ˜1.7 ns.

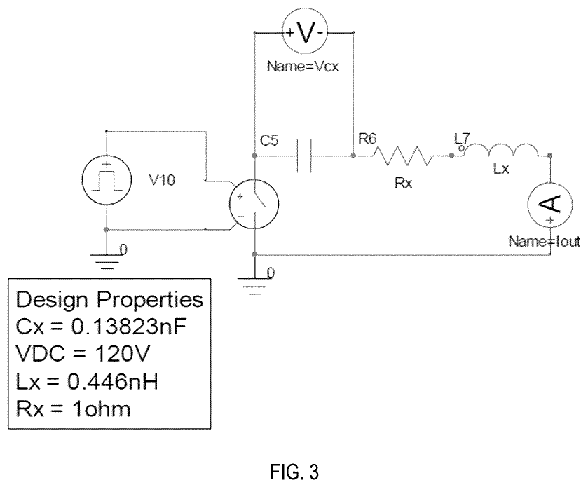

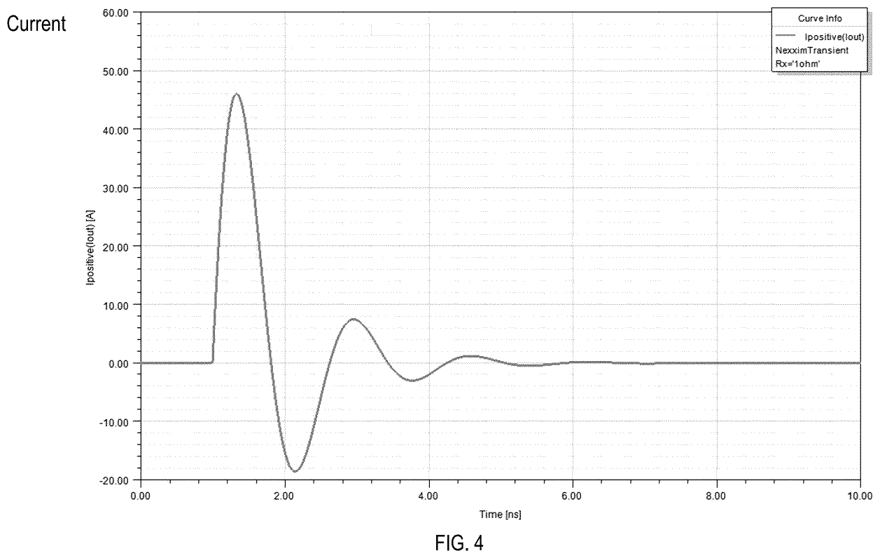

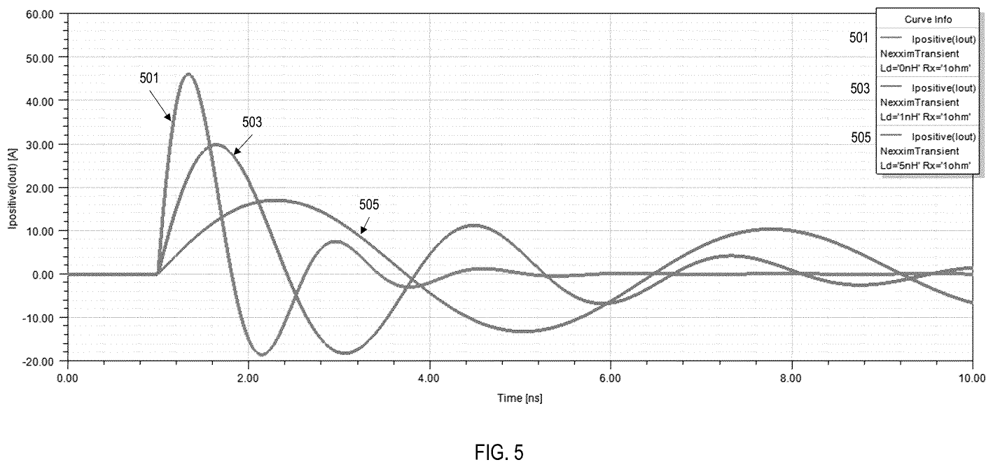

In the PicoLAS driver module, the capacitors Cx are charged over resistors Rx. When a pulse is applied at the trigger input, the MOSFET closes and the current flows from the capacitor through the laser diode, MOSFET, coil and resistors. Cx generates an oscillating circuit with the coil and the resistors. Due to the constant values of these elements the oscillating frequency and thereby the pulse width is kept constant. The output pulse is not affected by the length of the trigger input pulse. FIG. 3 illustrates an example driver model that simulates the behavior of the PicoLAS driver module. In the example shown in FIG. 3, the capacitor is pre-charged to the 120V and the switch closes to start the pulse. The capacitor and inductor values were chosen so that one half-cycle into a short is around 780 ps and the increase in pulse length with increasing load inductance follows the chart in the datasheet of the PicroLAS driver module. FIG. 4 illustrates an example experimental result corresponding to the example circuit model of FIG. 3. Increasing inductance to values such as 0 nH (501), 1 nH (503), and 5 nH (505) in the example driver model also increases the pulse width and decreases the amplitude of the current, as shown in FIG. 5.

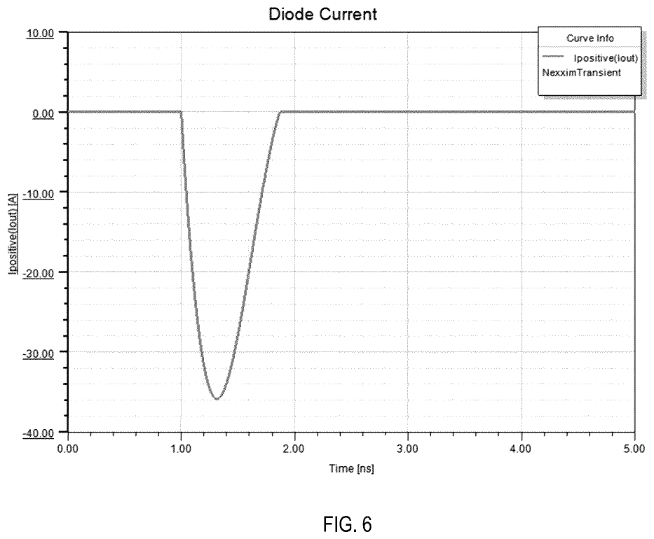

Regarding the behavior of a diode, a diode model was determined using simplified steady-state parameters estimated from an Osram diode package without a Zener diode, using the forward voltage curve at 25 degree Celsius. However, as shown in FIG. 6, which illustrates an example current plot of the simple diode model, this model is too simple to capture experimental details and no ringing was observed due to the rectifying effect of the diode.

To be able to construct a more realistic model, a Zener diode included in the Osram diode package was considered. Because the Osram diode package does not specify design values of the Zener diode, the following assumptions were made:
(1) the diode has a low forward turn-on voltage (0.3V), low forward/reverse on resistance (0.1 Ohm), and high speed;
(2) the Zener diode either trips slowly (several ns) or has a high reverse voltage threshold. The reverse voltage is set to 1 kV for simulations.

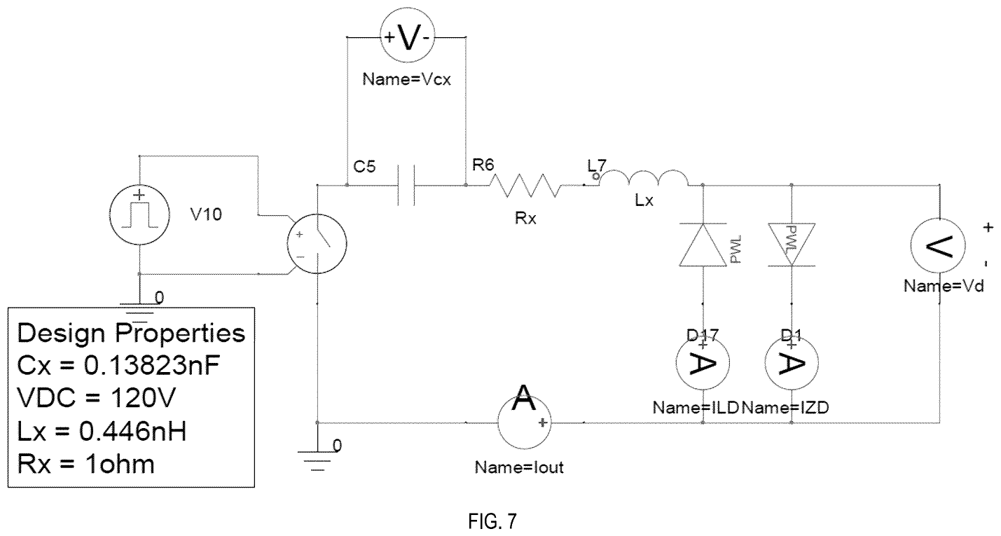

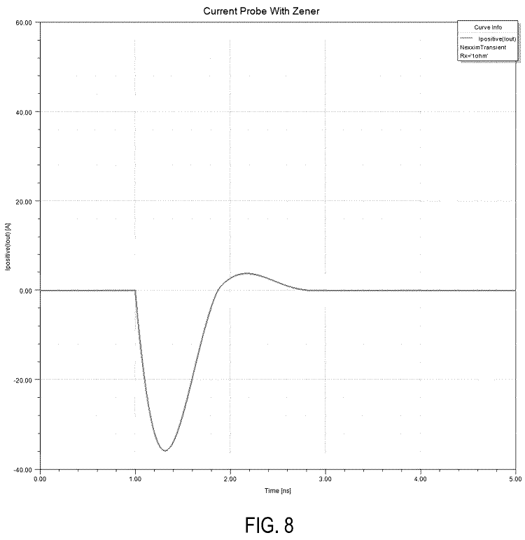

FIG. 7 illustrates an example diode model considering the addition of a Zener diode. As shown in FIG. 8, which illustrates an example current plot of the model in FIG. 7, adding the Zener diode allows some reverse current to flow, but does not allow for much late time ringing once voltage levels are below turn-on threshold.

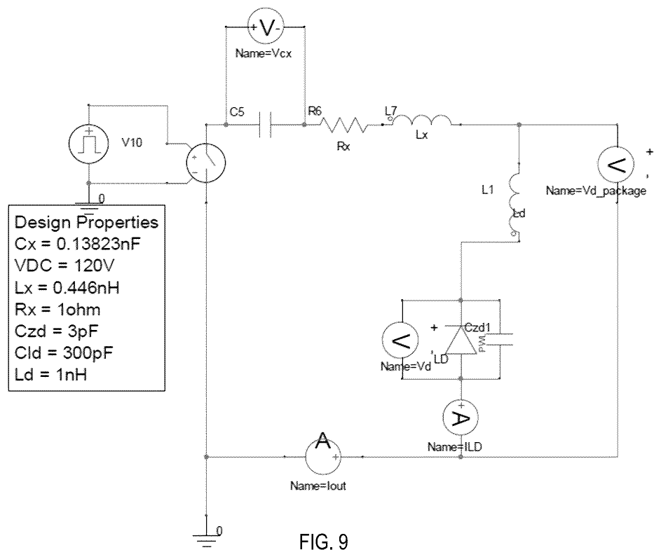

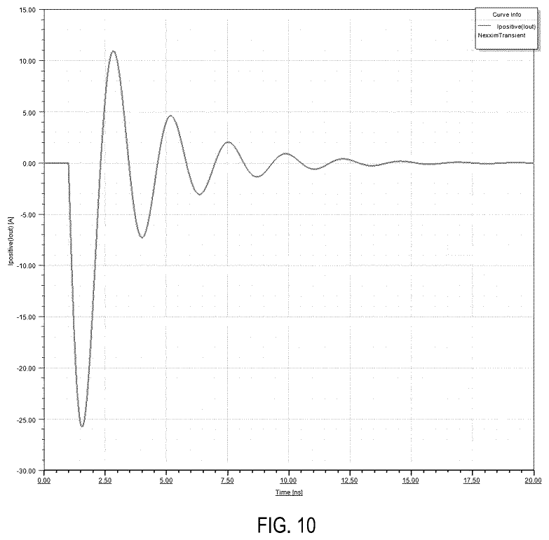

FIG. 9 illustrates an example parasitic diode model. In this example model, parasitic elements are added to the diode model to allow for the ringing seen in experiments. For example, 1 nH inductance Ld in series with diode to represent packaging inductance and 300 pF capacitance in parallel with diode. As shown in FIG. 10, the additional series inductance and parallel capacitance allow for the current to ring as seen in experiments, even without a Zener diode in the model.

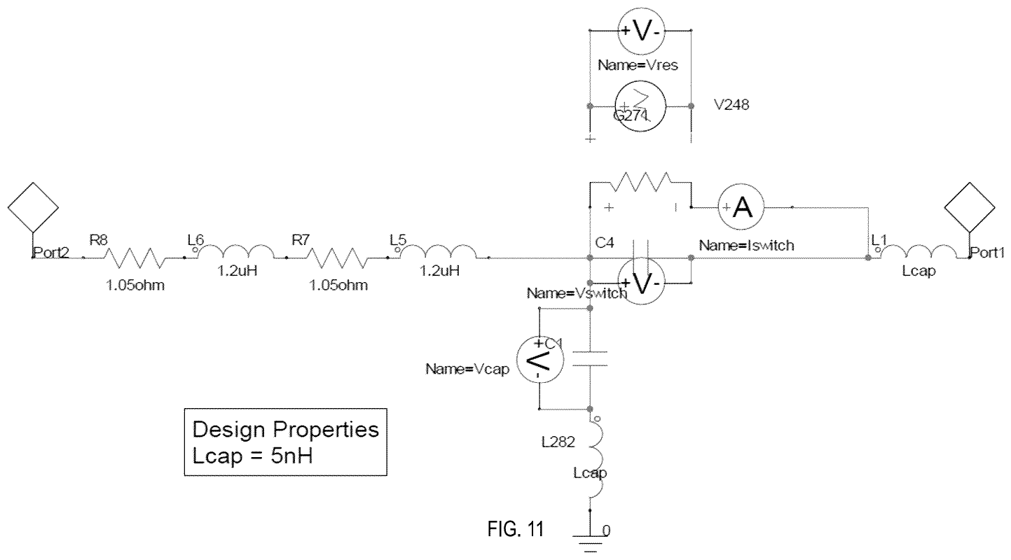

Given the understanding of the diode models, an example driver circuit can be designed to provide the desired pulse widths, to reduce ringing, and to improve switch performance. In particular, adding one or more resistor/inductors in series with the diode can reduce ringing and provide sufficient output current. FIG. 11 illustrates an example circuit model in which a switch is in series with a diode in accordance with one or more embodiments of the present technology. In this specific example, Port 1 is the output port to be connected to the diode and Port 2 is the charging port used to bring the energy storage capacitor C1 up to voltage. A total of 2.1 Ohms and 2.4 uH is connected to the charging port (Port2). The circuit includes a 2 pF switch capacitance (e.g., 1 mm thick SiC, with 2 mm radius active spot) that has 80 Ohms on resistance and a 2 nF storage capacitor. Two inductors (e.g., L5, L6) are connected between the input charging port and the switch to act as a Radio-Frequency (RF) choke or a filter. The inductance provides a high-impedance block to the pulses being generated, but a low impedance pathway to the slow charging of the energy storage capacitor. In FIG. 11, two series resistances are also used to simulate the winding resistance of the two inductors—the resistances can be removed as separate components in real implementations.

The inductance values of the inductors are selected to be enough to provide a first level of impedance (e.g., >>50 Ohms impedance) at the frequencies of the output pulse, and a second level of independence (e.g., <<50 Ohms impedance) at the frequency when the energy storage cap is recharged. Other arrangements to form an RF choke along the charging path can also be used. Components or traces can be arranged to form a lowpass filter with a cutoff that is well below the output pulse frequencies and an open-circuit effective impedance throughout the pulse frequencies.

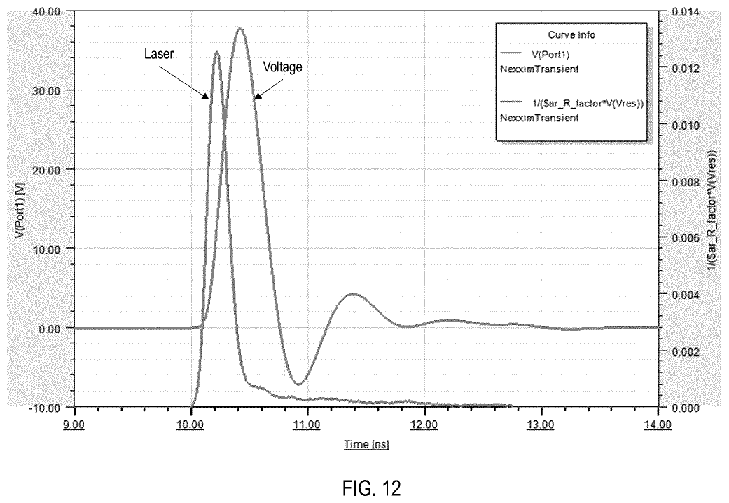

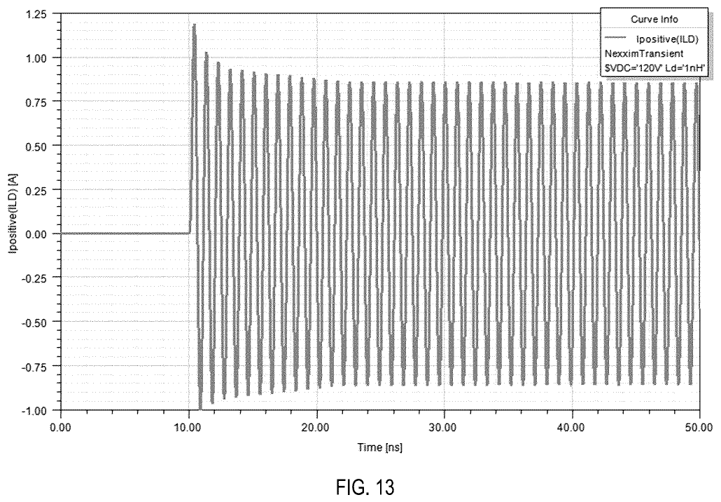

The circuit also includes 10 nH of parasitic inductance to match ringing. A 200 ps FWHM laser and a 355 ps FWHM output voltage were observed, as shown in FIG. 12. Connecting the simple diode model with inductive parasitic (e.g., as shown in FIG. 9) to the example circuit model, however, results in a current through the diode that rings for a very long time (e.g., as shown in FIG. 13). To remove the ringing and to create a short current pulse, a matching resister is added in series with the laser diode. The ideal total load impedance on the laser driver depends on the exact configuration. The diode impedance and load resistor value can be matched to the output transmission line impedance of the driver. For example, if the output transmission line is 50 Ohms for common conventions and the diode presents around 5 Ohms of total impedance when it is in the on state, a 45 Ohm resistor can be used for matching the transmission line and preventing reflections which lead to ringing. Other output transmission line impedances can also be chosen, and the value depends largely on the on resistance of the switch in the driver. It has been observed that the best results can be achieved when the output transmission line impedance is roughly equal to the switch on resistance.

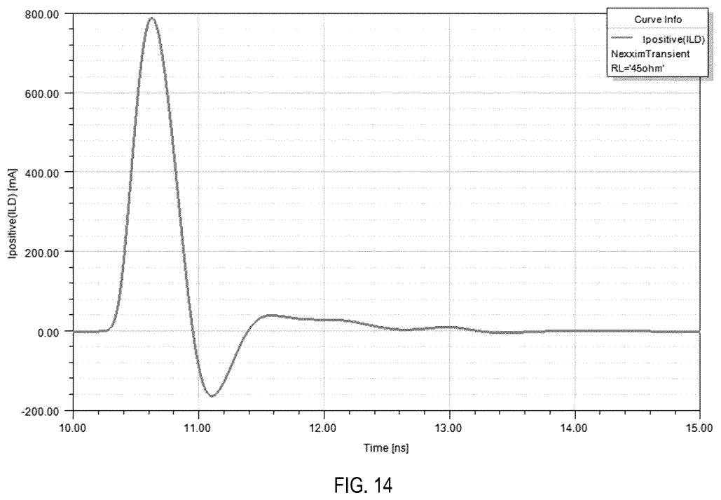

FIG. 14 illustrates an example current plot after introducing a matching resister in accordance with one or more embodiments of the present technology. As shown in FIG. 14, the peak current drops to around 800 mA with 120V charging. For a DC analysis, the 120V source sees about 125 Ohms resistance when the switch is on, making 800 mA a reasonable output when reactive effects are included.

It has been found that decreasing the switch on resistance and retuning the matching resistor can improve current output, at the cost of some ringing as the sensitivity to matching resistor value increases. Table 1 shows example on-resistance values and the resulting peak current values.

TABLE 1

| On Resistance (Ohms) | Peak Current (A) |
|---|---|
| 80 | 0.8 |
| 50 | 1 |
| 25 | 1.6 |
| 5 | 3.25 |

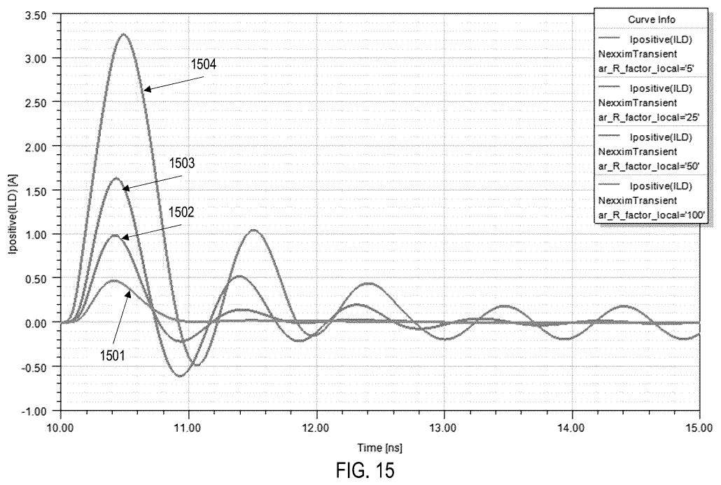

FIG. 15 illustrates example current plots of various on-resistance values in accordance with one or more embodiments of the present technology. In FIG. 15, curve 1501 corresponds to on-resistance of 100 Ohms, curve 1502 corresponds to on-resistance of 50 Ohms, curve 1503 corresponds to on-resistance of 25 Ohms, and curve 1504 corresponds to on-resistance of 5 Ohms. It can be seen in FIG. 15 that more ringing is observed as the on-resistance value decreases.

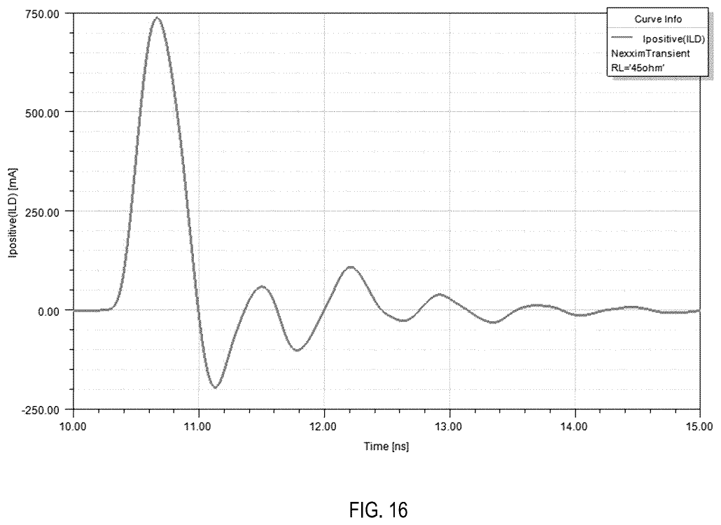

It is also found that connecting more diodes in series resulted in little reduction in output current. FIG. 16 illustrates an example current plot of five diodes connected in series in accordance with one or more embodiments of the present technology. As compared to FIG. 14, the peak current changes from 800 mA to 750 mA. There is also some increase in ringing due to extra inductance.

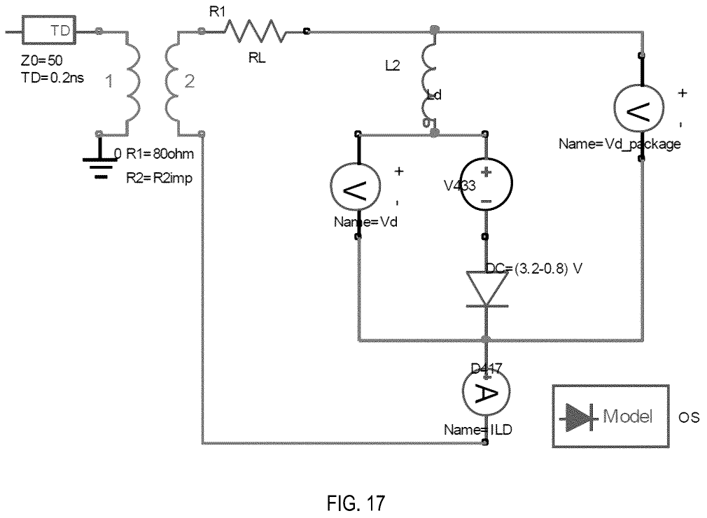

In some embodiments, an impedance transformer is used at the output to step up the current. A small 5 Ohm load resistance is used in series with the diode to provide damping. FIG. 17 illustrates an example configuration using an impedance transformer in accordance with one or more embodiments of the present technology. This example arrangement provides two times the current for the same VDC and switch resistance, at the cost of low levels of ringing.

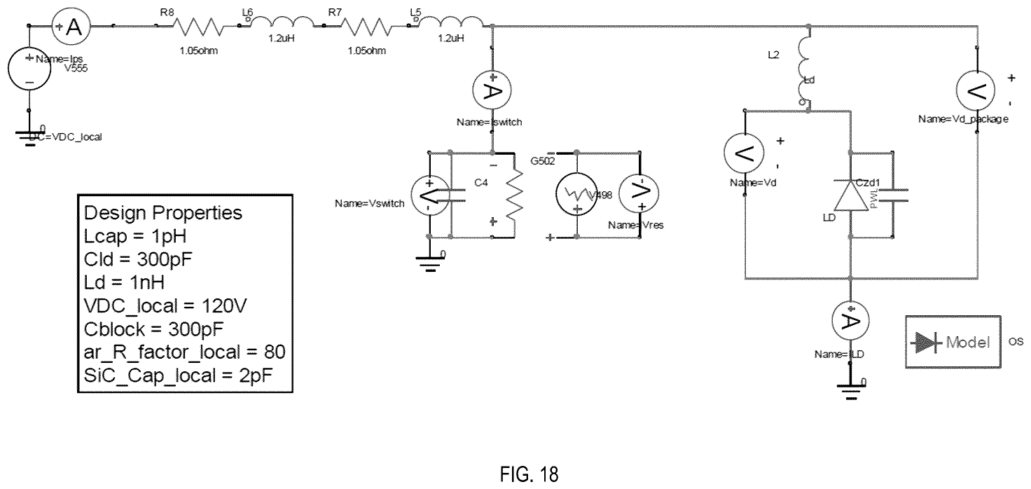

In some embodiments, parallel configurations of the circuit elements are used to improve the performance of the driver circuit and to increase output current. When parasitic inductances are low enough, a parallel configuration can provide more current than the corresponding series version. FIG. 18 illustrates an example circuit model in which a switch is in parallel with a diode in accordance with one or more embodiments of the present technology. The parasitic inductance of the laser diode being driven (e.g., the inductance of the mounting wires and internal bonded wires) can pair with parts of the drive circuit to form a resonance. For example, as shown in FIG. 18, the capacitance of the switch in the driver (C4) and the mounting inductance of the laser diode being driven (L2) can form a resonance. In order to prevent current ringing at the driven laser diode, the mount inductance is small enough that the resonant frequency is moved out of range of the frequencies in the driving pulse. In general, a value of the parasitic inductance is set based on both the duration of the driving pulse and the capacitance of the PCSS driver switch. For example, for duration pulses with FWHM ˜0.15-0.2 ps and the capacitance of the switch being ˜2 pF, a mounting inductance ˜0.5 pH was used to to avoid ringing and make the parallel-switch design a compelling choice. The example configuration shown in FIG. 18 can provide about two times the current as the series design (e.g., as shown in FIG. 11) for 80 Ohm switch on resistance. For 25 Ohm switch on resistance, this example configuration can provide about three times the current as the series design.

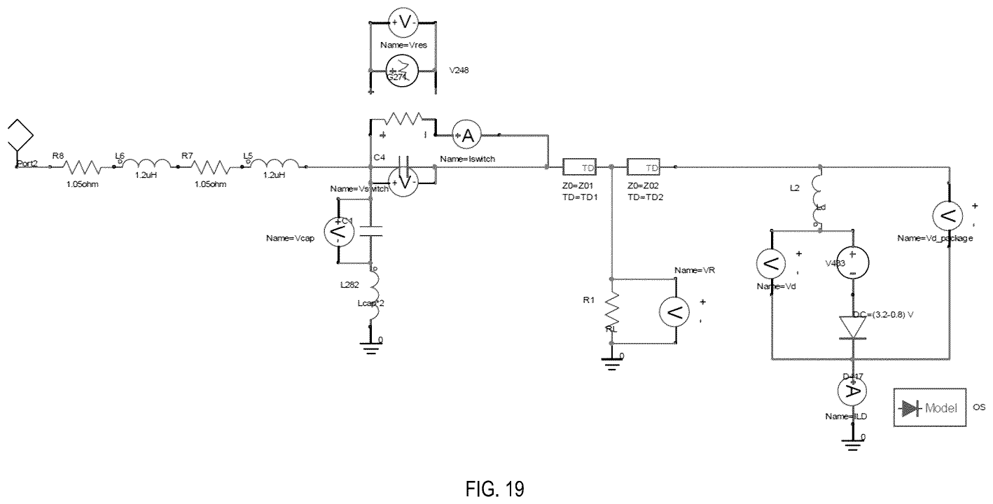

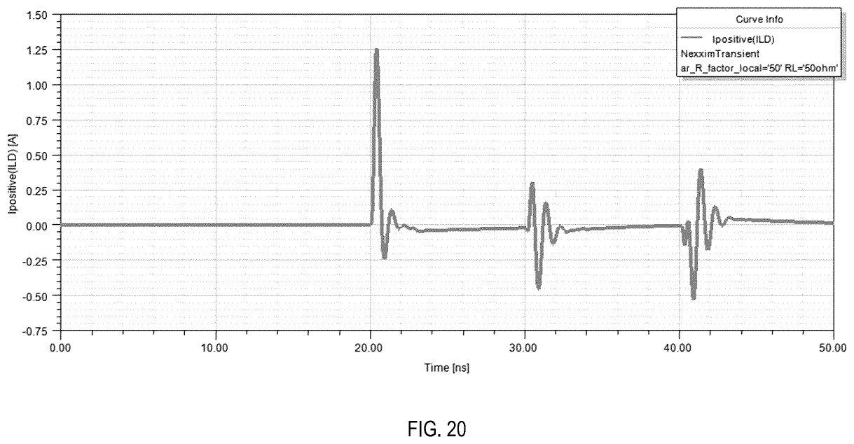

Parallel configurations of the load elements (e.g., diode and resistor) were also considered. The series configurations rely on eliminating reflections from the load to eliminate ringing. In parallel configurations, it is desired to determine whether a parallel matching resistor with delay lines can allow reflections from the load by absorbing reflections at the switch. Here, the concept is that if the switch is “off” and presents as an open circuit, the parallel resistor can absorb energy reflected from the diode. When the switch is activated, the pulse energy is split 50% toward the resistor and 50% toward the diode. FIG. 19 illustrates an example configuration in which the diode and resister are in parallel in accordance with one or more embodiments of the present technology. Using this example configuration, the initial current pulse is about 30% stronger than the series load case. The initial current pulse at the laser diode also has the same shape as in the series-matched case. However, as shown in FIG. 20, there are late-time reflections of significant magnitude. One cause of probable late-time ringing is that for higher frequencies, the switch does not function as an open circuit. For low frequencies, it has a high impedance as expected. However, the switch has a resonance just above 1 GHz where it functions like a short circuit rather than an open circuit. This behavior explains the distortions of the late time reflections. Design using this parallel concept need to change either the switch capacitance or power cap inductance to shift the resonance out of the working frequency range.

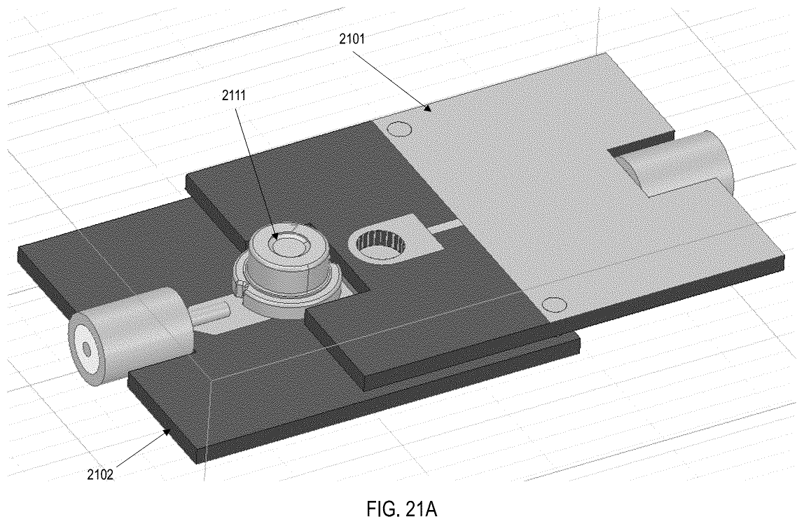

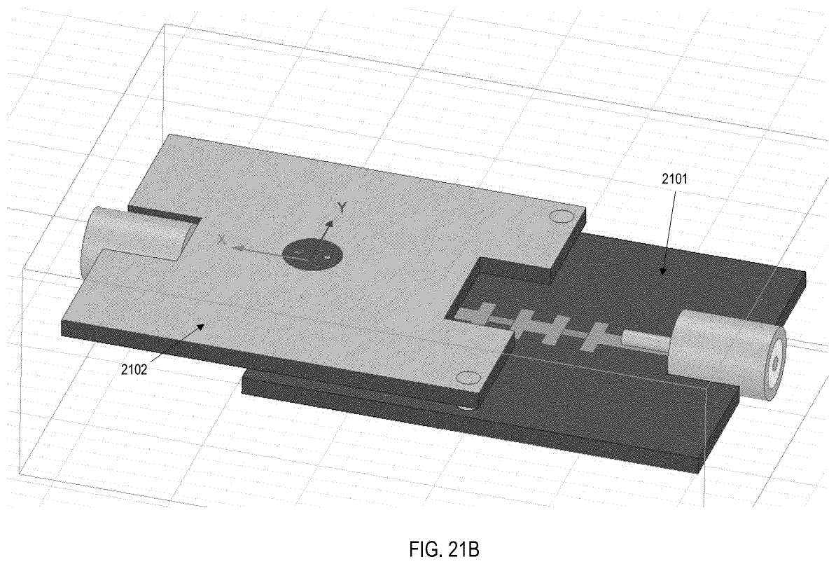

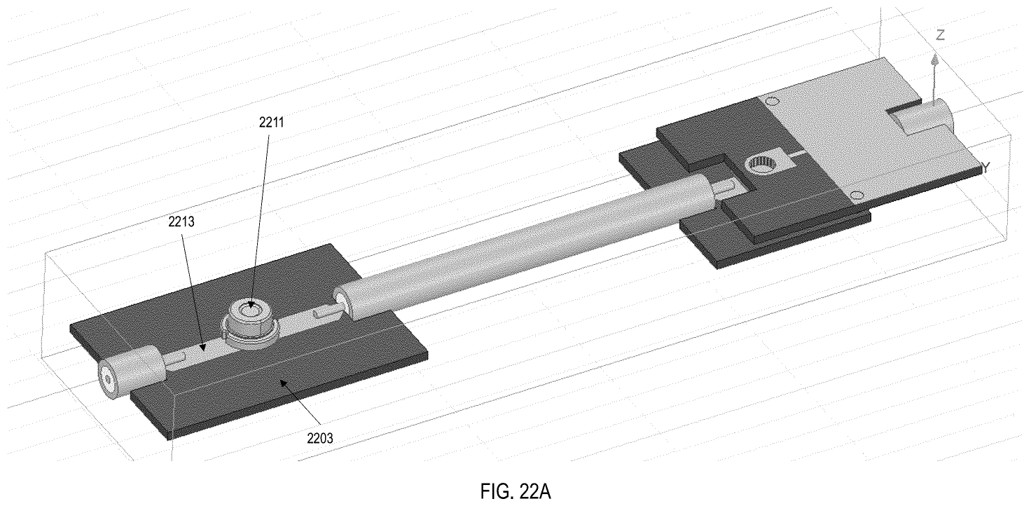

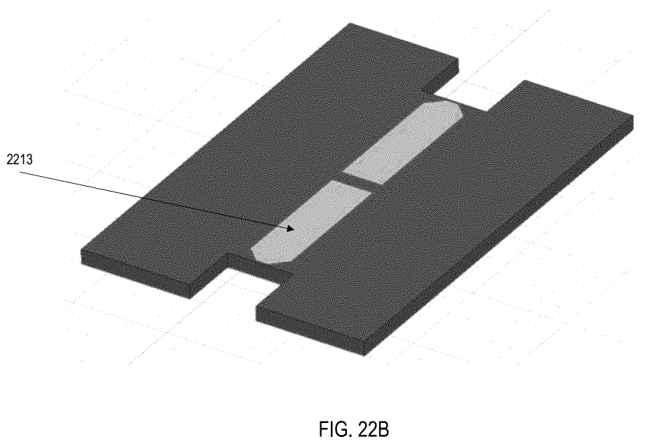

Based on the example circuit models (e.g., shown in FIG. 11 and FIG. 18), an actual implementation of the circuit using one or more circuit boards can be accomplished. For experimentation purposes, a Barksdale board intended to drive a standard 50 Ohm load is used as an implementation of the circuit board. However, different types of custom-made circuit boards (e.g., based on the disclosed circuit models above) can be used. FIGS. 21A-22B illustration two options in accordance with one or more embodiments of the present technology. FIG. 21A illustrates a top view of a first option using two circuit boards of difference sizes in accordance with one or more embodiments of the present technology. FIG. 21B illustrates a bottom view of the first option in accordance with one or more embodiments of the present technology. The bottom circuit board 2102 is longer than the top circuit board 2101 (e.g., 36 mm vs 27 mm) with room for the laser diode 2111 to be soldered in series along the main output trace. The ground plane is etched away around the diode mount so the leads can be inserted into drilled holes if desired. In some embodiments, the bottom circuit board 2102 is extended larger to provide adequate space for laser fiber or mounting (not shown). The output connector (e.g., subminiature version A, SMA, connector) is terminated in a load (e.g., 50 Ohm). Alternatively, or in addition, the termination option can include an attenuator or a scope to provide matching and allow for electrical operation to be monitored.

FIG. 22A illustrates a top view of a second option using a separate circuit board in accordance with one or more embodiments of the present technology. FIG. 22B illustrates a bottom view of the second option using a separate circuit board in accordance with one or more embodiments of the present technology. In some embodiments, two 50 Ohm connectors and a broken trace 2213 can be positioned on the additional circuit board 2203, as shown in FIGS. 22A-B, to allow the laser diode 2211 to be mounted. This board can be mounted to the output with a short cable or back-to-back connectors. The second option does not require modification of an existing board design. Using the second option, the output voltage pulse can be measured with and without diode load, and it is easier to expand to multiple diodes in series or alternate diode footprints. However, the second option is less compact as compared to the first option. There also exists a risk for reflections from imperfect connectors and increased inductance from cable length.

As mentioned above in connection with FIGS. 13-14, a matching resister needs to be added in series with the laser diode to remove or reduce ringing. It has been found that inline resistors placed between switch and diode are large and, if rated for very high voltage, contribute significant inductance (e.g., 50 nH). Therefore, it is desired to have termination resistors placed after the diode. The matching resister can be a flange-type resistor that is made to be mounted on microstrips and comes with a low cost (e.g., around $10-$15). Alternative types of resisters can also be used, such as a Pasternack high-power load that is bulkier and comes with a higher price.

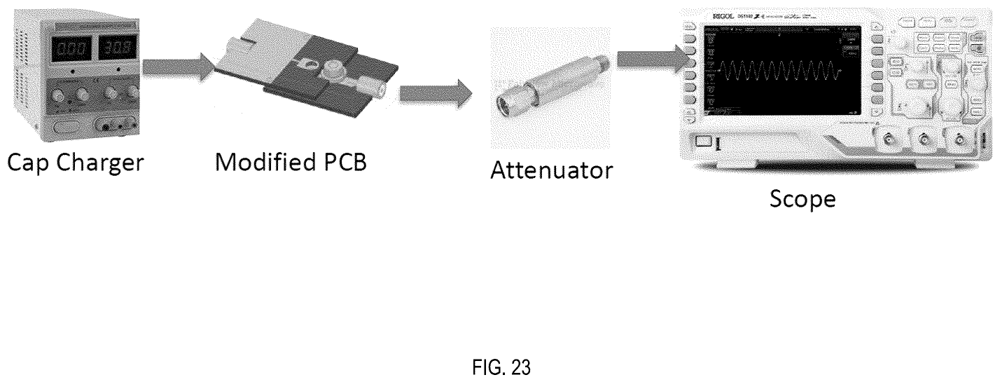

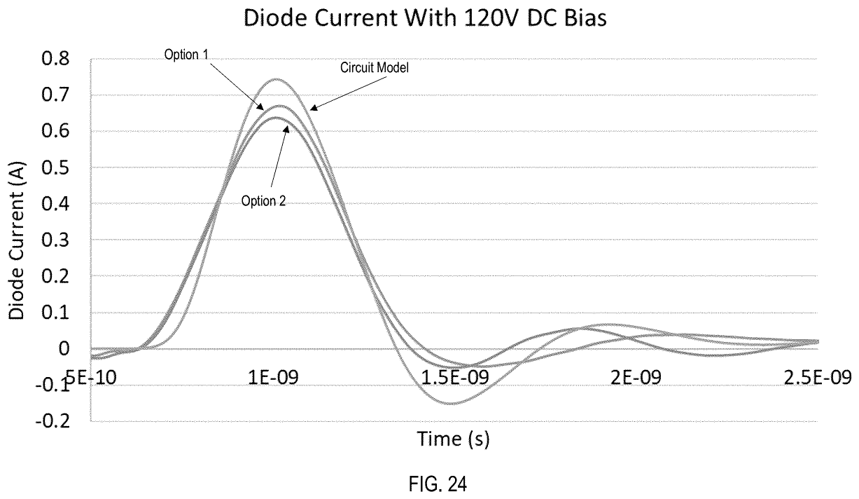

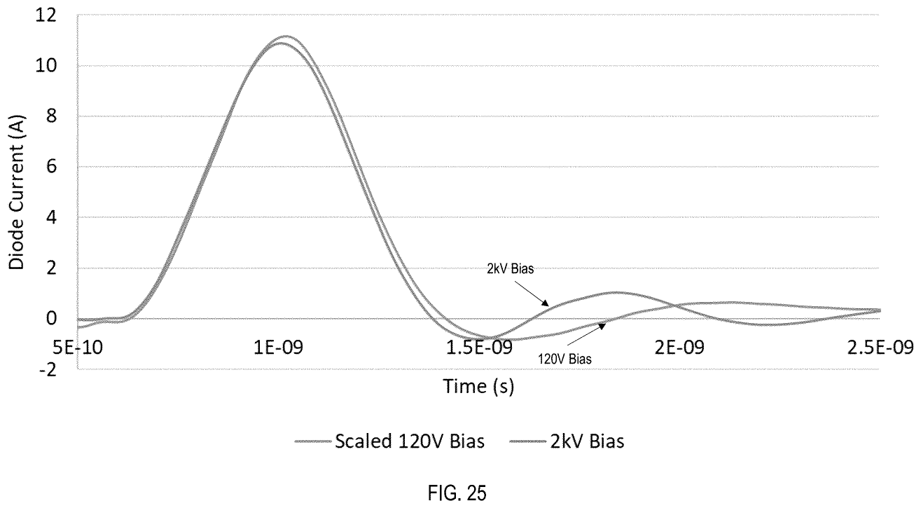

FIG. 23 illustrates an example configuration in accordance with one or more embodiments of the present technology. In this configuration, the output connector of the circuit board is connected through an attenuator into a scope to provide matched load and to enable electrical monitoring of experimentation. FIG. 24 illustrates example current plots of an example implementation of option 1, an example implementation of option 2, and a simulated circuit model. As shown in FIG. 24, results from the two example implementations of option 1 and option 2 match well, indicating that the integral diode mount and the separate diode bords both perform similarly. Furthermore, the performance of the example configuration scales well when the voltage increases. FIG. 25 illustrates example current plots of 2 kV and 120V in accordance with one or more embodiments of the present technology. The current results for 2 kV bias are almost identical to the 120V results. The non-linear properties of the diode model do not seem to cause a problem with performance as voltage scales.

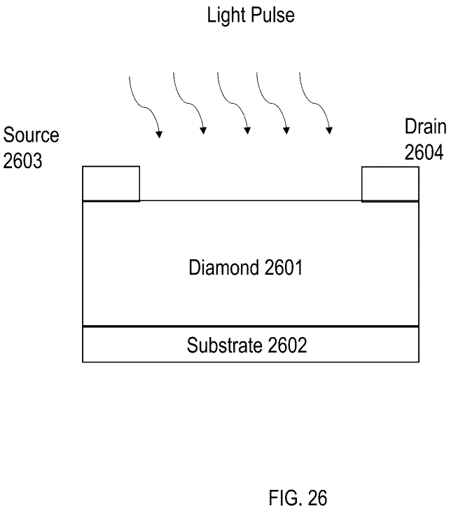

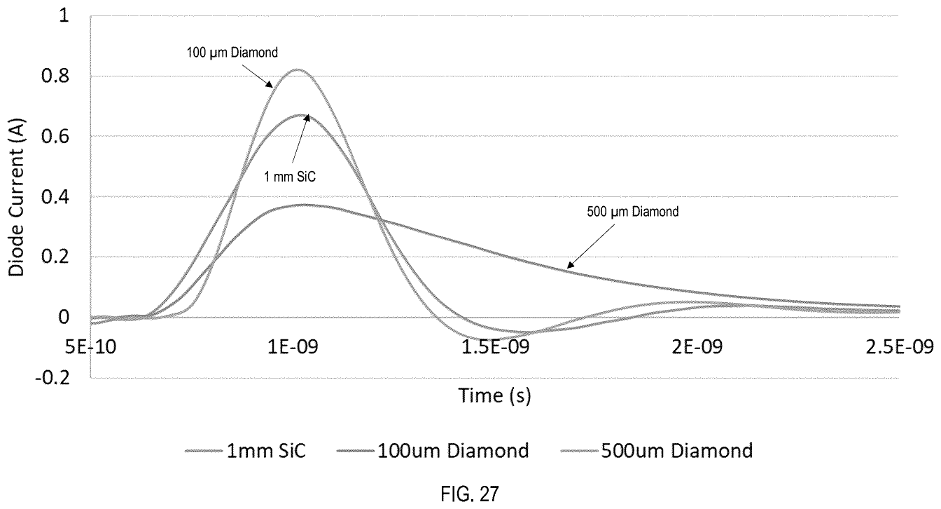

As mentioned above, in some embodiments, a switch capacitance is implemented using a 1 mm thick active region in SiC. In some embodiments, a diamond switch can be used. FIG. 26 illustrates a schematic diagram of a diamond switch. The diamond switch includes a source contact 2603, a drain contact 2604, and a diamond layer 2601 coupled to the source contact 2603 and the drain contact 2604. The diamond layer 2601 is positioned on a substrate 2602. In some embodiments, the diamond layer that has a thickness of about 500 μm can be used. The length and width of the diamond switch can be smaller than the SiC switch size, thereby reducing fringe capacitance. In some implementations, a 500 um diamond switch produces a higher amplitude and slightly shorter current pulse as compared to the SiC switch. FIG. 27 illustrates example current plots of an example 100 μm diamond layer, 500 μm diamond layer, and 1 mm SiC layer in accordance with one or more embodiments of the present technology.

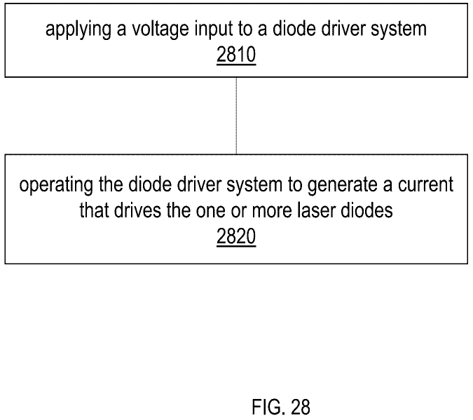

FIG. 28 is a flowchart representation of a method for driving one or more laser diodes in accordance with one or more embodiments of the present technology. The method 2800 includes, at operation 2810, applying a voltage input to an input port of a diode driver system. The diode driver system comprises one or more resistors and one or more inductors are coupled in series with the one or more laser diodes, a photoconductive switch coupled with the one or more resistors and the one or more inductors, the one or more laser diodes, and a terminating load coupled to the one or more laser diodes. The photoconductive switch comprises two electrodes, a semiconducting material connected to the two electrodes, a capacitor, and an optical source. The method 2800 includes, at operation 2820, operating the optical source of the photoconductive switch to emit an optical beam such that, upon the optical beam being emitted to the semiconducting material, a current is established between the two electrodes of the photoconductive switch. The current drives the one or more laser diodes to emit a pulse having a pulse width that is smaller than 50 ps.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described, and other implementations, enhancements and variations can be made based on what is described and illustrated in this patent document.

What is claimed is:

1. A circuit for driving one or more laser diodes, comprising:
an input port configured to be coupled to a voltage input;
one or more inductors that are configured to be in series with the one or more laser diodes;
a photoconductive switch coupled with the one or more inductors,
wherein the photoconductive switch comprises:
two electrodes,
a semiconducting material coupled to the two electrodes,
an optical source configured to emit an optical beam, and
a capacitor,
wherein, upon the optical beam being emitted to the semiconducting material, a current is established between the two electrodes; and
an output port configured to be coupled to the one or more laser diodes.

2. The circuit of claim 1, wherein an inductance value of the one or more inductors is determined based on charging the capacitor of the photoconductive switch and an output pulse from the one or more laser diodes.

3. The circuit of claim 1, wherein the circuit is part of a diode driver system that includes a terminating load coupled to the one or more laser diodes.

4. The circuit of claim 3, wherein the terminating load has a resistance value that, together with an impedance of the one or more laser diodes, substantially matches an output transmission line impedance of the circuit.

5. The circuit of claim 1, wherein the photoconductive switch is configured to be in a series connection with the one or more laser diodes.

6. The circuit of claim 1, wherein the photoconductive switch is configured to be in parallel connection with the one or more laser diodes.

7. The circuit of claim 1, further comprising:
a resistor configured to be in a parallel connection with the one or more laser diodes.

8. The circuit of claim 1, further comprising:
an impedance transformer coupled to the one or more laser diodes, configured to increase an output current from the one or more laser diodes.

9. The circuit of claim 1, wherein the voltage input is higher than 2 kV.

10. The circuit of claim 1, wherein the semiconducting material comprises a silicon carbide (SiC).

11. The circuit of claim 1, wherein the semiconducting material comprises a diamond.

12. The circuit of claim 1, wherein the circuit is part of a diode driver system that comprises:
a first circuit board that includes the input port, and
a second circuit board coupled to the first circuit board.

13. The circuit of claim 12, wherein the second circuit board comprises the output port, and
wherein the second circuit board has a larger size than the first circuit board to allow the one or more laser diodes to be soldered in series with an output trace on the second circuit board to the output port.

14. The circuit of claim 12, wherein the first circuit board and the second circuit board have a same site, wherein the circuit further comprises:
a third circuit board that comprises the output port and the one or more laser diodes, and
a connector configured to connect the third circuit board in series with the first circuit board and the second circuit board.

15. A method for driving one or more laser diodes, comprising:
applying a voltage input to an input port of a diode driver system,
wherein the diode driver system comprises:
one or more inductors in a series connection with the one or more laser diodes,
a photoconductive switch coupled with the one or more inductors,
wherein the photoconductive switch comprises two electrodes, a semiconducting material connected to the two electrodes, a capacitor, and an optical source,
the one or more laser diodes, and
a terminating load coupled to the one or more laser diodes; and
operating the optical source of the photoconductive switch to emit an optical beam such that, upon the optical beam being emitted to the semiconducting material, a current is established between the two electrodes of the photoconductive switch,
wherein the current drives the one or more laser diodes to emit a pulse having a pulse width that is smaller than 50 ps.

16. The method of claim 15, comprising:
operating the optical source of the photoconductive switch to terminate the optical beam such that the photoconductive switch and the one or more laser diodes are in an off state.

17. The method of claim 15, wherein the voltage input is higher than 2 kV.

18. The method of claim 15, wherein the semiconducting material comprises a silicon carbide (SiC) or a diamond.

19. The method of claim 15, wherein an inductance value of the one or more inductors is determined based on charging the capacitor of the photoconductive switch and an output pulse from the one or more laser diodes.

20. The method of claim 15, wherein the terminating load has a resistance value that, together with an impedance of the one or more laser diodes, substantially matches an output transmission line impedance.
